(19) United States
(12) Patent Application Publication
(10) Pub. No.: US 2009/0122633 A1
(43) Pub. Date: May 14, 2009

(54) INTEGRATED CIRCUIT WITH CONTROLLED POWER SUPPLY

(76) Inventor: Falk Roewer, Ottobrunn (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 11/939,704

(22) Filed: Nov. 14, 2007

(51) Int. Cl. G11C 5/14; H02J 1/00; G05F 5/00

(52) U.S. Cl. 365/226; 307/84; 307/80; 323/299

(57) ABSTRACT

An integrated circuit comprises a main circuit, a supply circuit configured to provide a supply current to the main circuit, a sensing circuit configured to sense the supply current, and a control circuit configured to control the supply circuit based on the sensed current.

### BACKGROUND OF THE INVENTION

Increased performance in modern electronic devices has been achieved using several methods such as operating the devices at increased clock speeds, widening busses that transfer data, and the like. The improvement in performance has usually come at the cost of increased power consumption. Increased power consumption may result in excessive heat generation which, in turn, may be harmful to device components and performance.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A through 1C show schematic views of exemplary integrated circuits according to embodiments of the invention;

FIGS. 2A and 2B show schematic views of exemplary supply circuits, sensing circuits, and control circuits according to embodiments of the invention;

FIG. 3 shows a schematic view of an exemplary supply circuit according to an embodiment of the invention;

FIGS. 4A and 4B show schematic sequential views of exemplary methods of operating an integrated circuit according to embodiments of the invention; and

FIG. 5 shows a schematic sequential view of an exemplary method of fabricating an integrated circuit according to an embodiment of the invention.

### DETAILED DESCRIPTION OF THE PREFERRED EMBODIMENT

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Embodiments of the invention may generally be used with any type of memory. In one embodiment, the memory may be a circuit included on a device with other types of circuits. For example, the memory may be integrated into a processor device, memory controller device, or other type of integrated circuit device. Devices into which the memory is integrated may include system-on-a-chip (SOC) devices. In another embodiment, the memory may be provided as a memory device which is used with a separate memory controller device or processor device.

Whether the memory is integrated into a device with other circuits or is provided as a separate device, the memory may be used as part of a larger computer system. The computer system may include a motherboard, central processor, memory controller, the memory, a hard drive, graphics processor, peripherals, and any other devices which may be found in a computer system. The computer system may be part of a personal computer, a server computer, or a smaller system such as an embedded system, personal digital assistant (PDA), or mobile phone.

In some cases, a device including the memory may be packaged together with other devices, typically referred to as a multi-chip package. Devices within the multi-chip package may be connected via wire bonds or other types of connections to a circuit board with one or more layers of interconnections. The devices and the circuit board may be enclosed within a packaging material such as a molded encapsulant or a ceramic packaging material. Such packages may include any other types of devices, including other devices with the same type of memory, other devices with different types of memory, and/or other devices including processors and/or memory controllers. Also, in some cases, the memory may be included in a device mounted on a memory module. The memory module may include other devices including memories, a buffer chip device, and/or a controller chip device. The memory module may also be included in a larger system such as the systems described above.

In some cases, embodiments of the invention may be used with multiple types of memory or with a memory which is included on a device with multiple other types of memory. The memory types may include volatile memory and non-volatile memory. Volatile memories may include static random access memory (SRAM), pseudo-static random access memory (PSRAM), and dynamic random access memory (DRAM). DRAM types may include single data rate (SDR) DRAM, double data rate (DDR) DRAM, low power (LP) DDR DRAM, and any other types of DRAM. Nonvolatile memory types may include magnetic RAM (MRAM), flash memory, resistive RAM (RRAM), ferroelectric RAM (FeRAM), phase-change RAM (PRAM), electrically erasable programmable read-only memory (EEPROM), laser programmable fuses, electrically programmable fuses (e-fuses), and any other types of nonvolatile memory.

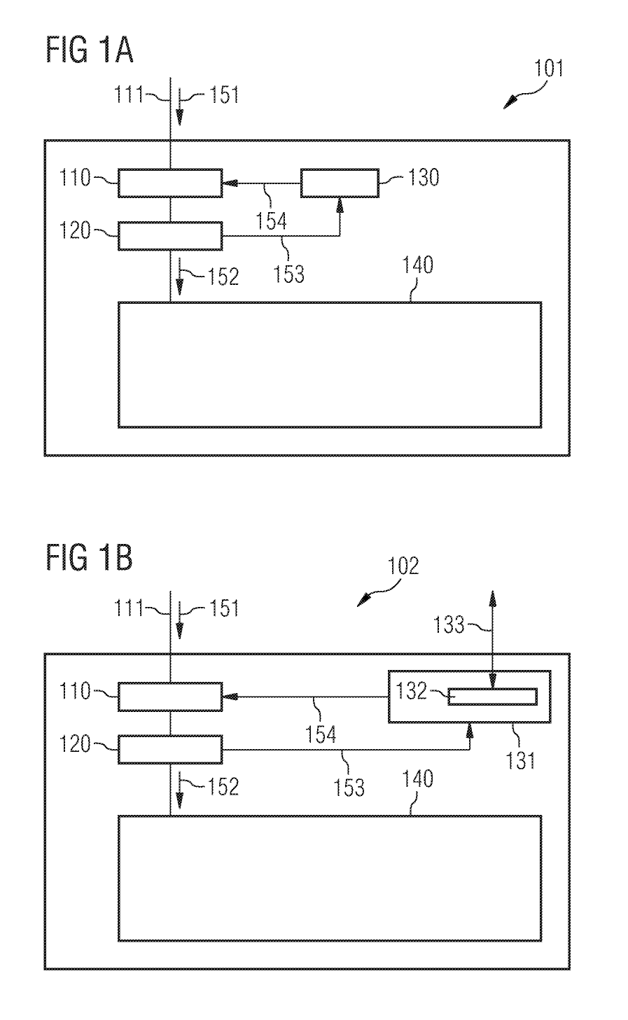

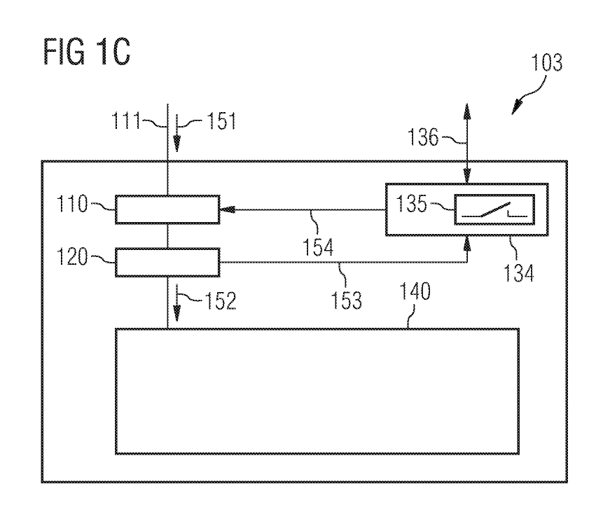

FIG. 1A shows a schematic view of an exemplary integrated circuit according to an embodiment of the invention. In one embodiment, an integrated circuit 101 may include a supply circuit 110, a sensing circuit 120, a control circuit 130, and a main circuit 140.

The supply circuit 110 may be connected to a power input 111 of the integrated circuit 101. The power input 111 may comprise terminals for connecting to a power supply of an external circuitry, such as a circuit system, a memory module, a multi chip module, or a computer system. In this way, the power input 111 may receive a circuit supply current 151, which may comprise one or more currents to the integrated circuit 101 and one or more currents from the integrated circuit 101. The terminals of the power input 111 may include a ground voltage terminal and a supply voltage terminal. The power input 111 may furthermore comprise more supply voltage terminals in order to, for example, provide different supply voltages in respect to a common ground potential to the integrated circuit 101, and/or to distribute a supply current to the integrated circuit 101 to more than one terminal. This may serve the purpose of a balanced distribution of a circuit supply current and/or the balancing of supply and ground potentials at different locations of the integrated circuit 101.

The supply circuit 110 may provide a supply current 152 to the main circuit 140. The supply current 152 may comprise one or more currents to the main circuit 140 and one or more currents from the main circuit 140. The supply circuit 110 may comprise circuitry to provide and/or regulate the supply current 152 based on the circuit supply current 151 received from the power input 111. In some embodiment, the supply circuit 110 may comprise any combination of a linear voltage regulator, a step-up converter, a step-down converter, a switching voltage regulator, a voltage pump, one or more power generators, operational amplifiers, voltage references, driver transistors, and related functional elements.

The main circuit 140 may comprise an integrated circuit, such as a memory circuit, a signal circuit, a central processing unit circuit, a signal processing unit, a logic circuit, an analogue circuit, and/or combinations thereof. In case the main circuit 140 comprises a memory circuit, the main circuit 140 may comprise sub-circuits such as a memory cell array, line decoders and column decoders, multiplexers, signal line drive circuits, and the like. The main circuit 140 may be operated in one or more operation modes, for example, enabled mode, active mode, disabled mode, hibernation mode, sleep mode, suspend mode, power safe mode, standby mode, and/or one or more different operation modes. The main circuit 140 may require and/or consume different median supply currents in its different operation modes. As an example, the main circuit 140 may require a maximal operation current in a normal operation mode, whereas a substantially lower supply current may be required by the main circuit 140 being in a disabled and/or power safe mode.

The sensing circuit 120 may sense the supply current 152, or the constituent partial currents thereof, being supplied by the supply circuit 110 to the main circuit 140. In one embodiment, the sensing circuit 120 may comprise a shunt, such as a resistor, a diode, a transistor, a field effect transistor (FET), an n-channel field effect transistor (NFET), or an FET providing a weak inversion. The shunt may furthermore comprise a semiconductor and/or a conductor. The shunt may convert a current into a voltage, which may, in turn, be converted into a digital value, for example, by means of an analog-to-digital converter (ADC). For example, in the case of a ohmic shunt, the voltage drop V along the shunt R may be linearly proportional to the current/flowing through the shunt, i.e.

V=R×I. (1)

In the case of a diode or transistor shunt, the voltage drop V along the shunt R may be proportional to a threshold voltage Vₜₕ and a dynamic compression In(I/Iₛ) according to

V=Vₜₕ×In(I/Iₛ). (2)

The sensing circuit 120 may in such a way sense the supply current 152 and convert it to a measured result 153, which may comprise an analog signal or a digital value.

In some embodiments, the measured result 153 of the supply current 152 may be fed back to a control circuit 130. The control circuit 130 may control the supply circuit 110 based on the measured result 153.

In one embodiment, the control circuit 130 may send a respective control signal 154 to the supply circuit 110. In this way, for example, the control circuit 130 may enable or disable individual power generators of the supply circuit 110, such as to enable only a required minimum number of power generators of the supply circuit 110 to provide the required current 152, leaving a remainder of power generators of the supply circuit 110 disabled and/or unused. Such disabled power generators of the supply circuit 110 may then be excluded from consuming unnecessary power. The supply circuit 110 may, however, comprise an excess number of individual power generators to allow for a sufficient and reliable power supply under conditions and/or operation modes of peak power consumption, or to allow for process variations during manufacturing or operation of the integrated circuit 101.

Power generators, such as voltage regulators, step-down converters, or step-up converters, convert an input current at an input voltage to an output current at an output voltage. Although modern switching voltage regulation schemes may attain a high efficiency, a fraction of the input power may be lost as heat during voltage conversion. In the case of a linear power regulator, the input voltage may exceed the required output voltage for an identical input and output current. The voltage difference between the input voltage and the output voltage, multiplied by the current may be, in such a case, lost as thermal heat within a shunt, such as a resistor, a diode, or a transistor.

FIG. 1B shows a schematic view of an integrated circuit according to an embodiment of the invention. An integrated circuit 102 comprises the supply circuit 110, the sensing circuit 120, the main circuit 140, and a control circuit 131. The supply circuit 110 receives the circuit supply current 151 for providing the supply current 152 to the main circuit 140, the supply current 152 being measured and converted into the measured result 153 by the sensing circuit 120.

According to the embodiment illustrated in FIG. 1B, the control circuit 131 may include a register 132. The register 132 may be accessible via a port 133 by external circuitry, such as a circuit system. The register 132 may store the measured result 153 as a digital value for one or more operation modes of the main circuit 140. The value being stored in the register 132 may have been converted to a digital value from a sensed voltage by the sensing circuit 120. The register 132 may furthermore store a value which controls the supply circuit 110 and/or the control circuit 131 may control the supply circuit 110 on the basis of the measured result 153, and may send a respective control signal 154 to the supply circuit 110.

According to the embodiment illustrated in FIG. 1B, an external circuit, may read the measured result from the register 132 which may correspond to the supply current 152. The external circuitry may, in this way, inform a system user or an operation system of the supply current 152 and/or a value representing power consumed by the integrated circuit 102. In this way, for example, a user of the circuit system may be informed of a remaining battery time, recent power consumption, and/or possibilities to conserve or save power. The value being stored in the register 132 may furthermore be set and/or altered by the external circuitry to control the supply circuit 110 from the outside of the integrated circuit 102. In this way, a recent value of the supply current 152 to the main circuit 140 may be sensed by means of the sensing circuit 120, may be stored in the register 132, may determine a controlling of the supply circuit 110, and may be transmitted to an external circuitry for information and/or further controlling purposes.

FIG. 1C shows a schematic view of an integrated circuit according to an embodiment of the invention. An integrated circuit 103 comprises the supply circuit 110, the sensing circuit 120, the main circuit 140, and a control circuit 134. The supply circuit 110 receives the circuit supply current 151 and provides the supply current 152 to the main circuit 140, the supply current 152 being measured and converted into the measured result 153 by the sensing circuit 120.

According to the embodiment illustrated in FIG. 1C, a control circuit 134 comprises a switch element 135. The control circuit 134 may be accessed from an external circuitry by means of a port 136. Furthermore the measured result 153, representing the sensed current 152 by the sensing circuit 120, may be accessed via the port 136. For such a purpose, the controlling circuit 134 may comprise a register such to store, at least temporarily, the measured result 153.

The switch element 135 may comprise any one of the group of a fuse, an e-fuse, an electronically settable fuse, a programmable read only memory (PROM) cell, a flash-RAM cell, a transistor with a consumable gate and/or channel. The state of a switch element 135 may control the supply circuit 110.

According to an embodiment, the switch element 135 may directly determine a state of one power generator of the supply circuit 110. In this way, for example, a switch element 135 may store the state of a respective power generator of the supply circuit 110. In the case the switch is in an open-state, the respective power generator may be set to an enabled state, hence outputting power. In the case the switch is in an open-state, the respective power generator may be set to an enabled state, hence outputting power. In the case the switch is in a closed-state, the respective power generator may be set to a disabled state, hence not outputting and conserving power. In alternative embodiments, the opposite may be true, for example, the power generator may be enabled by a closed switch and disabled by an open switch. The switch element 135 may be a non-volatile and stable switch element, i.e. the state of the switch element 135 may be retained even if the power supply to the integrated circuit 103 is switched off.

In this way, the integrated circuit 103 may be powered up and may be put into a specific operation mode, the supply current 152 in the respective mode may be sensed by means of the sensing circuit 120 and the measured result may be accessed from the outside by means of the control circuit 134 and the port 136. The state of the supply circuit 110 may be determined based on the measured result and the sensed current. Subsequently, for example, by means of instructing the control circuit 134 accordingly, the switch element 135 may be set. The setting of the switch element 135 may be effected directly, as high voltage pulses, for example to a gate of a transistor, may be necessary to program the switch element 135.

In some embodiment, the integrated circuit 103 may control the supply circuit 110 directly powering up, i.e. without sensing the supply current 152. This may further increase the device efficiency of the integrated circuit 103. A plurality of switch elements 135 may account for various operation modes of the integrated circuit 103 and may allow for a respective control of the supply circuit 110 by the control circuit 134. In this way, a required number of power generators may be enabled automatically when the integrated circuit 103 is powered up. At the same time, the power generators of the supply circuit 110, which are not required, may be automatically disabled through a respective setting of the switch element 135. Accordingly the integrated circuit 103 then generates only the necessary power for supplying a supply current to the main circuit 140.

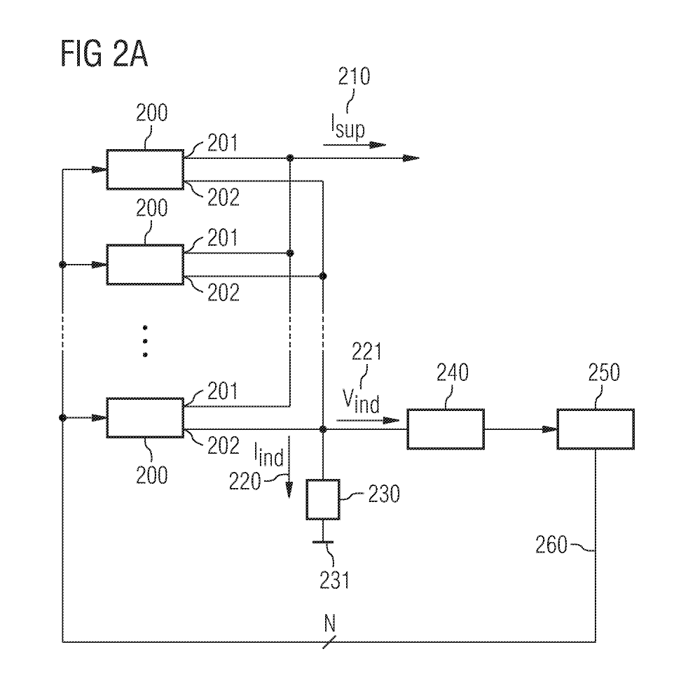

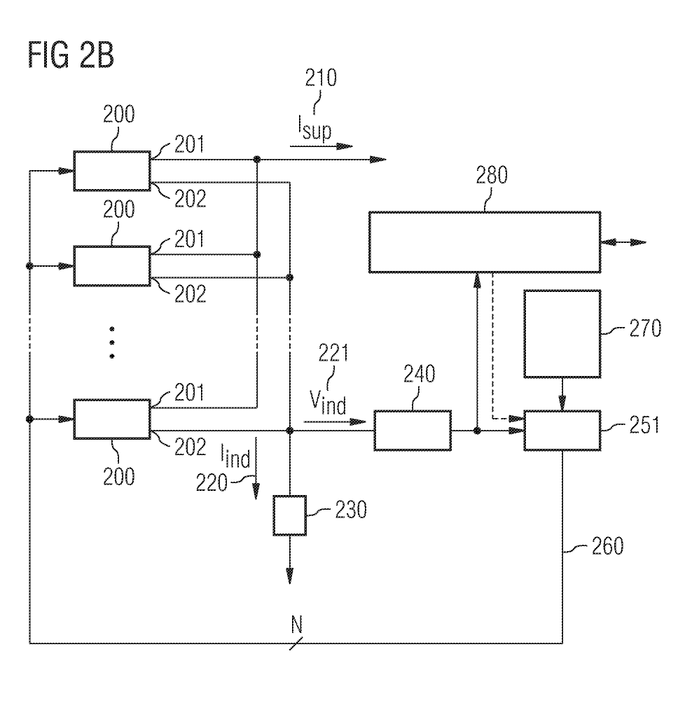

FIG. 2A shows a schematic view of a supply circuit, a sensing circuit, and a control circuit according to an embodiment of the invention. The supply circuit comprises power generators 200 that each comprise a supply current output 201 for supplying a partial supply current and an indicator current output 202 for providing a partial indicator current. Each partial indicator current is proportional to the partial supply current of the respective power generator 200. All partial supply currents are connected in parallel in order to provide a supply current Iₛᵤₚ 210 to a main circuit of an integrated circuit. In a similar manner, all partial indicator currents are connected in parallel in order to provide an indicator current I_{ind} 220. Hence, the indicator current I_{ind} 220 may be proportional or in a relation to the supply current Iₛᵤₚ 210 and a measurement of the indicator current I_{ind} 220 may allow for a determination of the supply current Iₛᵤₚ 210. Ratios of the supply current Iₛᵤₚ 210 and the indicator current I_{ind} 220 may include for example Iₛᵤₚ:I_{ind}=1:100, Iₛᵤₚ:I_{ind}=1:1000, or Iₛᵤₚ:I_{ind}=1:10000.

A sensing circuit 230 may sense the indicator current I_{ind} 220. The sensing circuit 230 may comprise a shunt, which is connected to a common reference potential, such as a ground potential 231. The sensing circuit 230 may further comprise a shunt, such as a resistor, a diode, and/or a transistor, such that the indicator current I_{ind} 220 may be converted into a indicator voltage V_{ind} 221. For example, in the case that the shunt of the sensing circuit 230 comprises a resistor, the indicator current I_{ind} 220 may be converted lineally into a indicator voltage V_{ind} 221 according to Eq. (1), which is proportionate to the indicator current. For another example, in the case that the shunt of the sensing circuit 230 comprises a diode or a transistor, the indicator current I_{ind} 220 may be converted into a indicator voltage V_{ind} 221 according to Eq. (2). Further examples for a conversion of the indicator current I_{ind} 220 into a indicator voltage V_{ind} 221 include a logarithmic conversion, an exponential conversion, and/or other conversions according to the respective IV-curve characteristics of the respective shunt element.

A further circuit 240 may convert the indicator voltage V_{ind} 221 at the sensing circuit 230 into a measured result or may simply forward the indicator voltage V_{ind} 221, for example as an analog signal, to the control circuit 250. The further circuit 240 may in such respective cases comprise a conversion circuit, such as an analog-to-digital converter (ADC) for providing a digital measured result by means of converting the analog indicator voltage V_{ind} 221 at the sensing circuit 230 into its digital representation. Such analog-to-digital conversion may also be carried out by the control circuit 250, the respective conversion circuit then becoming part of the control circuit 250.

By means of providing the measured result or the analog value signal to the control circuit 250, this control circuit 250 may determine, on the basis of the indicator voltage V_{ind} 221, a number of required power generators 200. In one embodiment, the control circuit 250 may set the respective modes of the power generators 200 via a control line 260 and, in this way, may disable or enable single power generators 200. In this way, the control circuit 250 may set only a required number of power generators 200 to an enabled mode, such that they each provide a partial supply current which sum up to a required supply current Iₛᵤₚ 210. By means of enabling only a required number of power generators 200, the power consumption being dissipated by each power generator 200 which is not required may be eliminated.

The supply current Iₛᵤₚ 210 may represent the actual current which is to be supplied to a main circuit of an integrated circuit. During operation of such a main circuit or in a specific operation mode of such a main circuit, a maximum supply current Iₛᵤₚ* may be required. Simultaneously, each power generator 200 may further be able to provide only a limited maximum partial supply current iₛᵤₚ*. A number n of required power generators 200 for supplying the maximum supply current Iₛᵤₚ* may than be represented by the next integer number following the fraction:

Iₛᵤₚ*/iₛᵤₚ* (3)

If the respective integrated circuit comprises N power generators 200, the remainder N-n of the power generators 200 may be disabled. The integrated circuit may comprise a number N power generators 200 such that N is always equal or greater than n for all operation modes and/or under all operation conditions, to allow for a reliable and uninterrupted power supply to the main circuit of the integrated circuit. According to an embodiment, the integer n may be increased by one or more, in order to account for a spare capacity of the supply circuit and in order to handle power consumption peaks within one operation mode in a reliable and efficient manner.

The actual number n may furthermore be dependent on an operation mode of the integrated circuit and may vary during testing, powering up, and/or operation of the integrated circuit. Since the indicator current I_{ind} 220 may be in a relation to the supply current Iₛᵤₚ 210, examples may be given for a supply current Iₛᵤₚ to be of the order of 10 mA, an indicator current I_{ind} to be of the order of 10 μA, a shunt resistance to be of the order of 100 kΩ, and a resulting indicator voltage V_{ind} to be of the order of 1 V. A current which may be consumed by one of the voltage generators when enabled but not supplying a partial supply current may be of the order of 0.1 mA, 0.5 mA, or 1 mA. Such a quiescent current may be saved and suppressed, if the power generator 200 which is not required is disabled. It is to be noted, that such a current may be saved per disabled power generator 200, and, hence, the overall power saving may be substantial.

FIG. 2B shows a schematic view of a supply circuit, a sensing circuit, and a control circuit according to an embodiment of the invention. The supply circuit may include power generators 200 that each comprise the supply current output 201 for supplying the partial supply current and the indicator current output 202 for providing the partial indicator current. The indicator current I_{ind} 220 is converted into the indicator voltage V_{ind} 221 by means of the sensing circuit 230. The indicator voltage 221 is converted into a measured value by the further circuit 240 and fed to the control circuit 251 in order to enable the control circuit 251 to controls the power generators 200 and may set their enabled or disabled modes accordingly.

According to this embodiment, also a communication circuit 280 may receive the measured result from the further circuit 240, and may store the measured result in a register and/or may transmit the measured result to an external circuitry, such as to a circuit system or computer system. The communication circuit 280 may furthermore communicate with the control circuit 251 in order to determine and/or influence the controlling of the power generators 200. In this way, the controlling of the power generators 200 by the controlling circuit 251 may be supervised, verified, broadcast, determined, and/or influenced by an external circuitry or system, such as an operation system, by means of the communication circuit 280.

Furthermore, a chip control circuit 270 may be coupled to the control circuit 251 in order to determine and/or influence the controlling of the voltage generators 200. Such a chip control circuit 270 may control the main circuit of the integrated circuit and/or an operation mode of such a main circuit. Since the chip control circuit 270 may determine or set an operation mode of the main circuit and the operation mode of the main circuit may affect the required supply current Iₛᵤₚ 210, an updated controlling of the power generators 200 may have been rendered necessary. By means of the coupling of the control circuit 251 to the chip control circuit 270 a respective communication and/or signaling may be carried out, such as a transmission of a power mode or operation mode from the chip control circuit 270 to the control circuit 251. In this way, the control circuit 251 may enable or disable respective numbers of power generators according to an operation mode of the main circuit, the operation mode being set by the chip control circuit 270. Situations in which an updated controlling may be necessary may include transitions from a power save mode to an active operation mode, a transition from a sleep mode to a normal mode, or vice versa.

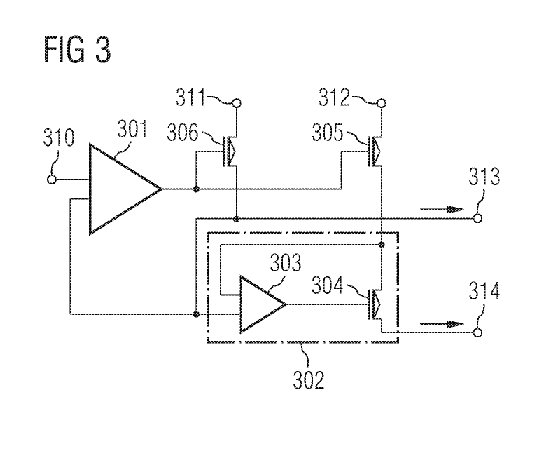

FIG. 3 shows a schematic view of a power generator according to an embodiment of the invention. The power generator may include an operational amplifier 301, an output driver transistor 306, a sensing transistor 305, and an active cascode 302. The transistors 304, 305, and/or 306 may comprise a field effect transistor (FET) or a p-channel field effect transistor (PFET). The operational amplifier 301 may act as a comparator which may compare a reference voltage being supplied by a reference terminal 310 and a voltage at the power output driver 306. The operational amplifier 301 furthermore drives the power output driver 306 and the sensing transistor 305 by means of their respective gates. The power output driver transistor 306 and the sensing transistor 305 may comprise field effect transistors, power field effect transistors, and the like. The output driver transistor 306 and the sensing transistor 305 are connected to terminals 311 and 312 respectively, which may both be coupled to circuit power supply. The output of the power driver transistor 306 is coupled to an output 313 which supplies the partial supply current iₛᵤₚ.

The active cascode 302 comprises a further operational amplifier 303 and a further output transistor 304. The operational amplifier 303 of the active cascode 302 may act as a comparator and may compare the voltage at the power output driver transistor 306 to the voltage at the sensing transistor 305, and may accordingly drive the output transistor 304 of the active cascode 302. In this way, the active cascode 302 provides a partial indicator current i_{ind} at an indicator terminal 314 being proportional to the partial supply current iₛᵤₚ at the supply terminal 313.

The ratio of the partial supply current iₛᵤₚ at the supply terminal 313 and the partial indicator current i_{ind} at the terminal 314 may be given by a ratio of respective transistor widths W₁ and W₂ as

i_{ind}=iₛᵤₚ(W₂/W₁), (4)

W₁ being the transistor width of the driver transistor 306 and W₂ being the transistor width of the sensing transistor 305.

Taking into account the respective transistor widths W₁ and W₂, the indicator voltage may be deducted from

V_{ind}=Iₛᵤₚ×R×(W₂/W₁) (2a)

or

V_{ind}=Vₜₕ×In(W₂/W₁+I/Iₛ), (2b)

respectively, depending on whether a linear resistive shunt [Eq. (2a)] or a diode-like shunt [Eq. (2b)], is employed as a current-voltage-conversion element.

The active cascode 302 may furthermore regulate the drain-source voltage of the sensor transistor 305 to the value of the output voltage at the supply output 313. This may provide an optimized matching of the current mirror. The driver transistor 306 may be furthermore part of a linear voltage regulator. In this way, an output voltage Vₒ at the supply terminal 313 may be less than an input voltage Vᵢ at the terminals 311 and 312, the output voltage being regulated on the basis of a supplied reference voltage 310. The voltage differential in such a regulator configuration then may determine the amount of power being dissipated as heat within the regulator or power generator and, in general, lost. This power may be calculated from the voltage differential to be

P=(iₛᵤₚ+i_{ind})×(Vᵢ−Vₒ). (5)

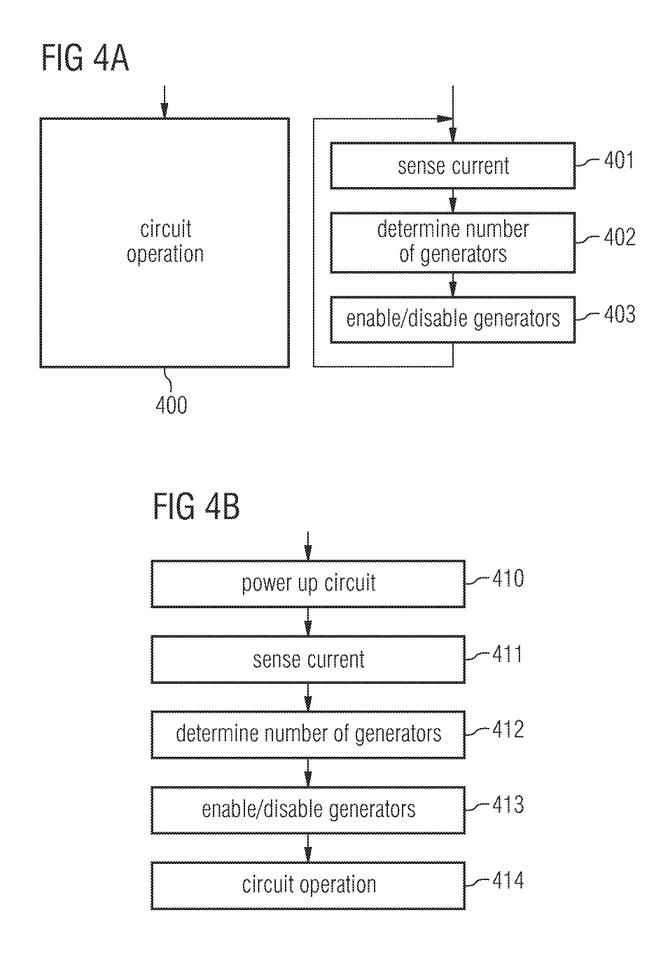

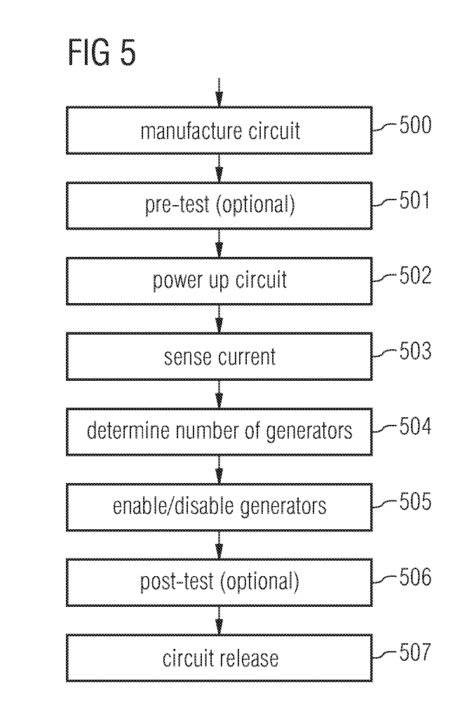

FIG. 4A shows a schematic sequential view of an exemplary method of operating an integrated circuit according to an embodiment of the invention. According to the exemplary method illustrated in FIG. 4A, at least two parallel processes may be executed in a substantially simultaneous manner. The circuit operation 400 may comprise all functional processes that may run or may be executed in the main circuit of an integrated circuit. Simultaneously, the supply current to such a main circuit is sensed in stage 401. On the basis of the sensed current the required number of power generators may be determined in stage 402. According to such a determined number, the required generators are enabled, whereas the remainder of the generators, be comprised by the integrated circuit and not being required, is disabled in stage 403.

Such a determination and setting of enabled and disabled modes of power generators may be executed continuously to allow for take into account changes and variations of the supply current and/or changes of an operation mode of the main circuit. Hence, the process may be led back from stage 403 to stage 401. Furthermore, the integrated circuit may continuously supervise the supplied current and may adapt the actually required power generators in this way. An optimized number of enabled power generators may hence be attained, and the integrated circuit may generate only the actually required current and, in this way, may minimize the required power supply and/or minimize the generation of excess heat. According to this embodiment, the actual power consumption of an integrated circuit or a main circuit thereof may be measured in real time and the required number of generators may be adapted dynamically.

FIG. 4B shows a schematic sequential view of an exemplary method of operating an integrated circuit according to an embodiment of the invention. Accordingly, the integrated circuit is powered up during stage 410, which may include a powering up of all comprised sub-circuits of the integrated circuits, such as a main circuit. Furthermore, the powering up stage 410 may include a setting of an operation mode of the integrated circuit. The supplied current to the main circuit is then measured in stage 411. According to the sensed and measured current, a number of required power generators is determined in stage 412. On the basis of the determined number, the required power generators are enabled, whereas the remainder of the power generators, which are comprised by the integrated circuit, may be disabled in stage 413. Having set the number of required power generators to an enabled mode and remainder of the power generators to a disabled mode, regular operation 414 of the main circuit and/or integrated circuit may commence or continue.

According to this embodiment, the actually required supply current for the integrated circuit is sensed at a powering up 410 of the integrated circuit. Such a powering up 410 may be conducted when the integrated circuit is switched on, connected to a supply voltage, activated by an external circuit system, and/or by resuming the integrated circuit and the circuit system from a suspended mode. In this way, the integrated circuit may be operated with a minimum of required power generators. Furthermore, the actually required current and the required number of power generators may be determined upon each powering up 410 of the integrated circuit. In this way, variations in operation parameters, such as operation temperature, operation mode, and/or other parameters may determine a proper setting of the respective enabled and disabled modes of the power generators, since such variations may affect the actually required supply current.

FIG. 5 shows a schematic sequential view of an exemplary method of fabricating an integrated circuit according to an embodiment of the invention. Accordingly the integrated circuit is manufactured by means of a manufacturing process 500. The manufacturing process 500 may comprise a plurality of process stages for manufacturing substrates, stacks of substrates, functional elements, signal lines, connections, packages, carrier substrates, and the like. For example, such process stages may be part of a CMOS or related manufacturing process for manufacturing highly integrated circuits.

The integrated circuit is optionally tested during a pretest stage 501. Such a pretest stage 501 may include optical or mechanical testing and inspection which may not require an actual connection to the integrated circuit. Furthermore the pretest stage 501 may comprise a connection to testing equipment and/or to electrical connections which may allow a powering up of the circuit in powering up stage 502.

Having powered up the integrated circuit, the actually provided supply current to the integrated circuit in the powered up state may be sensed during stage 503. Such a sensing may be carried out by means of internal sensing circuits of the integrated circuit and/or external sensing circuits of respective test equipment. An internally sensed current may be transmitted to test equipment by means of a conversion circuit and/or communication circuit.

Subsequently, the number of the required power generators is determined in stage 504. Accordingly a required number of power generators are enabled, whereas the remainder of the power generators, which are comprised by the integrated circuit, may be disabled in stage 505. Such an enabling and/or disabling of the power generators 505 may comprise a setting of switch elements of the integrated circuit and/or writing a value into a register of the integrated circuit. Such a register value may represent the respective enabled mode or disabled mode of each power generator. For example a binary number of M bits length may directly set the enabled/disabled modes of M power generators, the mth bit being “0”, for example, disabling the mth power generator and the mth bit being “1” enabling the mth power generator. A setting of a switch element may include a blowing of a fuse element, an application of a voltage pulse, a destruction of a conductor, or a destruction of a transistor gate. After an optional post-test stage 506, the integrated circuit may be released in stage 507.

According to this embodiment, a plurality of integrated circuits may be manufactured in an identical manner. However, process variations may result in a varying actual supply current of the integrated circuit. Such an actual supply current may be determined by the method according to this embodiment, this, for example, during a front-end test stage and/or a back-end test stage. Accordingly each integrated circuit may be manufactured comprising a minimum or excess number of power generators and then be tested and set such that only an actually required number of power generators is enabled, whereas the remainder of the power generators is disabled. In this way, the power consumption and the generation of excess heat within each integrated circuit may be minimized, since excess power generation within unrequired power generators is suppressed. This may provide an integrated circuit with an increased performance, an increased reliability, an improved buffer capacity of the circuit's supply circuit, an optimized power consumption, an enhanced lifetime, a broader applicability, for example, in mobile applications, and/or an enhanced environmental friendliness. Such applications may then provide an improved reliability and/or an enhanced battery run time.

The preceding description only describes exemplary embodiments of the invention. The features disclosed therein and the claims and the drawings can, therefore, be important for the realization of the invention in its various embodiments, both individually and in any combination. While the forgoing is directed to the embodiments of the present invention, other and further embodiments of this invention may be devised without departing from the basic scope of the invention, the scope of the present invention being determined by the claims that follow.

What is claimed is:

1. An integrated circuit comprising
a main circuit;
a supply circuit configured to a supply current to the main circuit;
a sensing circuit configured to sense the supply current; and
a control circuit configured to control the supply circuit based on the supply current sensed by the sensing circuit.

2. The integrated circuit as claimed in claim 1, wherein the supply circuit provides an indictor current, wherein the indicator current is proportional to the supply current.

3. The integrated circuit as claimed in claim 1, wherein the supply circuit comprises one or more power generators, outputs of the one or more power generators being connected in parallel, wherein the outputs provide the supply current, and wherein each power generator is configured to operate in an enabled state and a disabled state, wherein, in the enabled state, each power generator is configured to output a partial supply current.

4. The integrated circuit as claimed in claim 3, wherein the power generators are configured to provide the partial supply current at the outputs and a partial indicator current, the partial indicator current being proportional to the partial supply current.

5. The integrated circuit as claimed in claim 4, wherein the sensing circuit comprises a shunt, wherein a sum of the partial indicator currents from one or more enabled power generators is configured to flow through the shunt.

6. The integrated circuit as claimed in claim 5, wherein the sensing circuit comprises an analog to digital converter, wherein the analog to digital converter is configured to convert a voltage at the shunt to a current value.

7. The integrated circuit as claimed in claim 6, wherein the sensing circuit comprising a register for storing the current value, wherein the register is readable through a port.

8. The integrated circuit as claimed in claim 7, wherein the control circuit comprises a switch element, the state of the switch element determining the state of a power generator.

9. The integrated circuit as claimed in claim 8, wherein the switch element is any one of a transistor, a fuse, an electrically programmable fuse, an e-fuse, an SRAM cell, a flash-RAM cell, a PROM cell, and an EPROM cell

10. The integrated circuit as claimed in claim 6, wherein the control circuit sets the states of the power generators on the basis of the current value.

11. The integrated circuit as claimed in claim 1, wherein the sensing circuit comprises a shunt, wherein the supply current is configured to flow through the shunt.

12. The integrated circuit as claimed in claim 1, wherein the sensing circuit comprising an analog to digital converter configured to convert the supply current into a current value.

13. A memory device comprising
a memory circuit;
one or more power generators configured to provide a supply current to the memory circuit, each power generator having an enabled state and a disabled state, wherein each power generator outputs a partial supply current if in the enabled state and no current if in the disabled state;
a sensing circuit configured to sense the current being supplied to the memory circuit; and
a control circuit configured to control the power supply circuit based on the sensed current.

14. The memory device as claimed in claim 13, wherein the control circuit sets the states of the power generators based on a value of the current.

15. The memory device as claimed in claim 14, wherein the sensing circuit comprises a register for storing the value of the current, wherein the register is readable through a port.

16. The memory device as claimed in claim 13, wherein the control circuit comprises a switch element, the state of the switch element determining the state of a power generator.

17. The memory device as claimed in claim 13, wherein the memory circuit comprising an array of memory cells, wherein the memory cells are one of a DRAM cell, a flash RAM cell, a PC-RAM cell, a CB-RAM cell, an M-RAM cell, and an S-RAM cell.

18. A method of operating an integrated circuit, the integrated circuit comprising a main circuit and one or more power generators providing a supply current to the main circuit, the method comprising:
sensing the supply current being provided to the main circuit;
determining a number of power generators required for providing the supply current;
enabling the number of power generators;
disabling the remaining power generators of the integrated circuit.

19. The method as claimed in claim 18, wherein sensing the supply current comprises converting a voltage to a numerical value.

20. The method as claimed in claim 18, wherein enabling a power generator and disabling the power generator comprises setting a state of the power generator, wherein the power generator provides a partial supply current in an enabled state and no current in a disabled state.

21. A method of manufacturing an integrated circuit, the integrated circuit comprising a main circuit and one or more power generators providing a supply current to the main circuit, the method comprising:
powering up the integrated circuit;
sensing the supply current being provided to the main circuit;
determining a number of power generators required for providing the supply current;
enabling the number of power generators; and
disabling the remaining power generators of the integrated circuit.

22. The method as claimed in claim 21, wherein sensing the supply current comprises:
sensing a voltage at a current shunt;
converting the sensed voltage into a numerical value;
writing the numerical value into a register; and
reading the numerical value from the register.

23. The method as claimed in claim 21, wherein sensing the supply current comprises measuring a current provided to the integrated circuit.

24. The method as claimed in claim 21, wherein enabling a power generator and the disabling a power generator comprises setting of a switch element.

25. The method as claimed in claim 21, wherein the number of power generators enabled is based on the operation mode of the integrated circuit.
